(19) United States
(12) Patent Application Publication
(10) Pub. No.: US 2025/0239507 A1
(43) Pub. Date: Jul. 24, 2025

(54) IC PACKAGE WITH DIE AND COPPER POSTS

(71) Applicant: TEXAS INSTRUMENTS INCORPORATED, DALLAS, TX (US)

(72) Inventors: GUANGXU LI, ALLEN, TX (US); RAJEN MANICON MURUGAN, DALLAS, TX (US); SYLVESTER ANKAMAH-KUSI, McKINNEY, TX (US)

(21) Appl. No.: 18/416,432

(22) Filed: Jan. 18, 2024

(51) Int. Cl. H01L 23/495; H01L 23/00; H01L 25/065

(52) U.S. Cl. CPC H01L 23/49575; H01L 23/4951; H01L 24/13; H01L 24/29; H01L 25/0652; H01L 2224/13005; H01L 2224/13022; H01L 2224/29006; H01L 2224/29022; H01L 2924/01029; H01L 2924/182

(57) ABSTRACT

An IC (integrated circuit) package includes an interconnect having a substrate with pads and a die having moisture channels and bond pads. The IC package includes copper posts formed on the bond pads of the die. The copper posts are coupled of the pads of the substrate. The IC package also includes a mold compound encapsulating the die, the copper posts and a portion of the interconnect.

### TECHNICAL FIELD

This description relates to a die with an IC (integrated circuit) package that includes copper posts coupled to a die and an interconnect.

### BACKGROUND

Moisture in IC (integrated circuit) packages presents issues that impact both reliability and performance. When moisture is trapped in IC packages, the moisture leads to a variety of problems in some situations. Corrosion of metal parts within the package is a common issue, leading to electrical failures. In some cases, trapped moisture causes delamination. Wire bonds inside the package, leveraged for electrical connections can be weakened by moisture in some examples. Additionally, during high-temperature processes like soldering, trapped moisture vaporizes and expands, causing the IC package to crack or “popcorn”, rendering the IC package damaged and possibly useless in some instances. Moisture also leads to electrical leakage or short circuits, adversely affecting performance. Furthermore, moisture alters the dielectric properties of materials in the IC package in some examples, impacting timing and signal integrity.

Delamination in an IC package refers to the phenomenon where layers within the package, which are normally bonded together, start to separate or split apart. This separation can occur between various layers such as a die and a substrate, between the substrate and an encapsulant (e.g., mold compound) or within the layers of the substrate. In some examples, delamination disrupts internal connections and impairs of functionality of the IC package.

### SUMMARY

A first example relates to an IC (integrated circuit) package including an interconnect having a substrate with pads and a die having moisture channels and bond pads. The IC package includes copper posts formed on the bond pads of the die. The copper posts are coupled of the pads of the substrate. The IC package also includes a mold compound encapsulating the die, the copper posts and a portion of the interconnect.

A second example relates to a method for forming an IC package including boring moisture channels in a die of a wafer and forming a metTop layer on a die of the wafer. The method also includes forming copper posts on the die of the wafer and dicing the wafer to provide the die. The method further includes mounting the copper posts of the die on a substrate of an interconnect with solder paste and reflowing the solder paste to adhere the copper posts on the substrate. The method includes encapsulating the die, the copper posts and a portion of the interconnect in a mold compound.

### BRIEF DESCRIPTION OF THE DRAWINGS

FIG. 1 illustrates a cross-section view of an IC (integrated circuit) package that includes a die with moisture channels.

FIG. 2 illustrates an overhead view of an IC package that includes moisture channels.

FIG. 3A illustrates a moisture map of a conventional IC package that does not include moisture channels.

FIG. 3B illustrates a moisture map of an IC package with moisture channels.

FIG. 4A illustrates a conventional IC package with a die mounted on an interconnect that does not include moisture channels.

FIG. 4B illustrates the IC package of FIG. 4A after a preconditioning operation.

FIG. 4C illustrates the IC package of FIGS. 4A and 4B after the preconditioning operation and after a temperature cycle.

FIGS. 5-13 illustrates stages of a method for fabricating an IC package.

FIG. 14 illustrates a flowchart of an example method for fabricating an IC package.

### DETAILED DESCRIPTION

This description relates to an IC (integrated circuit) package that includes a die having moisture channels (e.g., through holes). The die also includes bond pads that are attached to copper posts. The copper posts are mounted on an interconnect (e.g., a lead frame) having a substrate with pads. A mold compound encapsulates the die, the copper posts and a portion of the interconnect. The IC package provides improved moisture resistance and reliability by incorporating the moisture channels within the die. More particularly, during reflow at a preconditioning operation, moisture (e.g., water vapor) escapes through the moisture channels and permeates through the mold compound to curtail delamination of layers of the IC package.

In some situations, the moisture channels are formed proximate a center region of the die. In this manner, moisture at the center region of the die is reduced, thereby reducing the chances of the delamination.

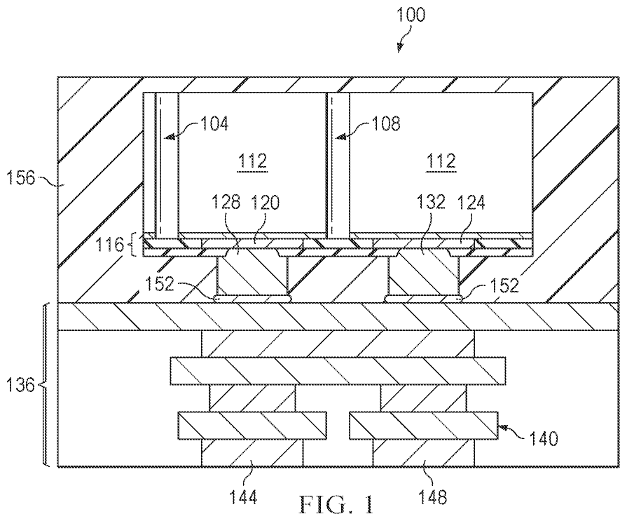

FIG. 1 illustrates an IC (integrated circuit) package 100 that includes a first moisture channel 104 and a second moisture channel 108. Although the present example illustrates two (2) moisture channels, in other examples, there are more or less moisture channels. The first moisture channel 104 and the second moisture channel 108 are formed in a die 112 of the IC package 100. In some examples, the IC package 100 has a flip-chip architecture. Thus, the IC package 100 includes a metTop layer 116 (alternatively referred to as a metalized top layer). The metTop layer refers to metal pads that provide bond pads, namely a first bond pad 120 and a second bond pad 124 for the die 112. In other examples, there are more or less bond pads formed by the metTop layer 116. The metTop layer 116 is formed such that metal pads forming the metTop layer 116 circumscribe the first moisture channel 104 and the second moisture channel 108.

A first copper post 128 is formed on the first bond pad 120 and a second copper post 132 is formed on the second bond pad 124 of the die 112. The copper posts are alternatively referred to as copper pillars. The first copper post 128 and the second copper post 132 are attached to a substrate 136 of an interconnect 140. In other examples, there are more or less copper posts. The interconnect 140 is alternatively referred to as a lead frame. The interconnect 140 also includes a first lead 144 and a second lead 148 that enables the die 112 to communicate with external circuits. In other examples, there are more or less leads. In some examples, the IC package 100 is a quad flat no-leads (QFN) IC package. In other examples, the IC package 100 is a dual flat no-leads (DFN) IC package.

The first copper post 128 and the second copper post 132 are attached to the substrate 136 with solder 152, such as solder paste. A mold compound 156, such as plastic encapsulates the die 112, the first copper post 128, the second copper post 132 and a portion of the interconnect 140 (e.g., the first lead 144 and the second lead 148 are exposed).

During fabrication of the IC package 100, moisture (e.g., water in liquid and/or vapor form) is trapped in the IC package 100. This moisture causes delamination in some examples. More particularly, during post preconditioning (e.g., a thermal cycle) of the IC package 100, the trapped moisture expands at a different rate than other materials of the IC package 100. To curtail delamination of the layers of the die 112 (which layers include the first copper post 128, the second copper post 132 and/or the interconnect 140), the first moisture channel 104 and the second moisture channel 108 are included to enable water vapor to pass therethrough. The first moisture channel 104 and the second moisture channel 108 have a diameter in a range of about 40 micrometers to about 200 micrometers (or even larger in some examples). For instance, in some examples, the first moisture channel 104 and the second moisture channel 108 have a diameter of about 100 micrometers. Moreover, the mold compound 156 has a water vapor transmission rate of about 2-8 milligrams per square meter per day (mg/(m²d)), such as at least 3 mg/(m²d). Thus, over time, the water vapor of the moisture trapped in the IC package 100 escapes through the first moisture channel 104 and the second moisture channel 108. This water vaper permeates through the mold compound 156 over time to curtail changes of delamination of layers of the IC package 100.

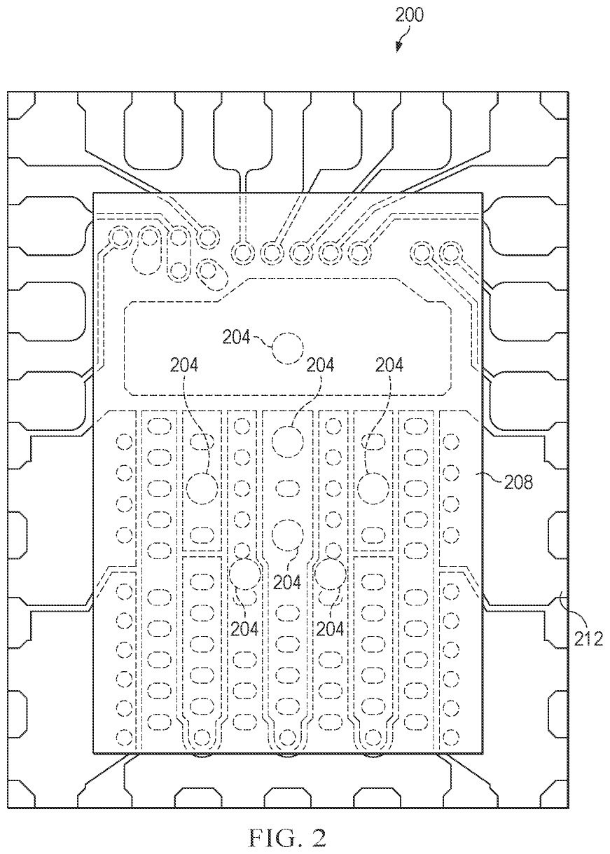

FIG. 2 illustrates an overhead view of an IC package 200 that includes moisture channels 204. The IC package 200 is employable to implement the IC package 100 of FIG. 1. Similarly, the moisture channels 204 are employable to implement the first moisture channel 104 and/or the second moisture channel 108 of FIG. 1. The moisture channels 204 are formed in a die 208 that is mounted on an interconnect 212. Moreover, for illustrative purposes many components of the IC package 100 have been removed or made transparent.

As demonstrated by the IC package 200, the moisture channels 204 are proximate a center region of the die 208. In many instances, the center region of the die 208 has a greatest amount of moisture trapped therein. Thus, the moisture channels 204 enable the moisture to be released from the IC package 200 to curtail delamination of the layers of the IC package 200.

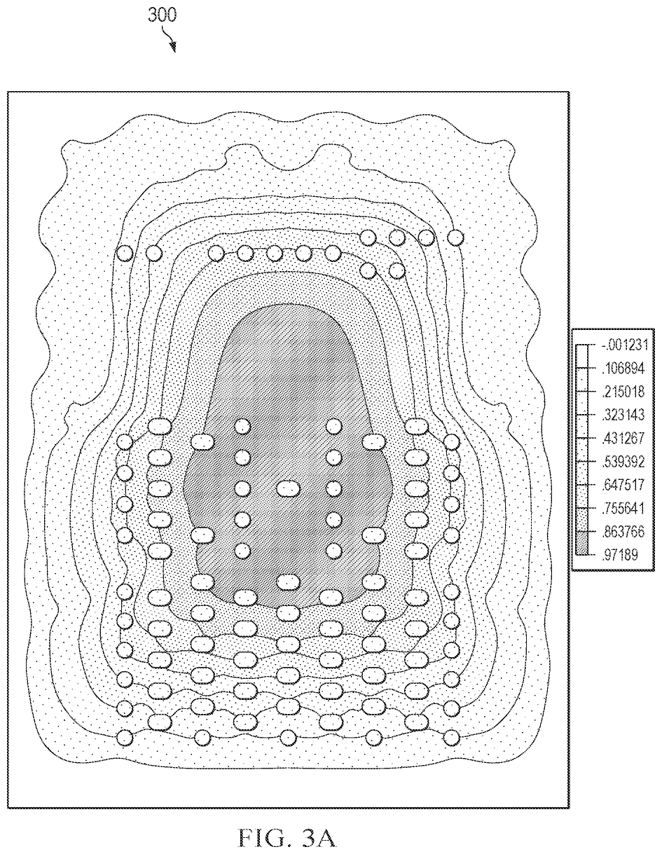

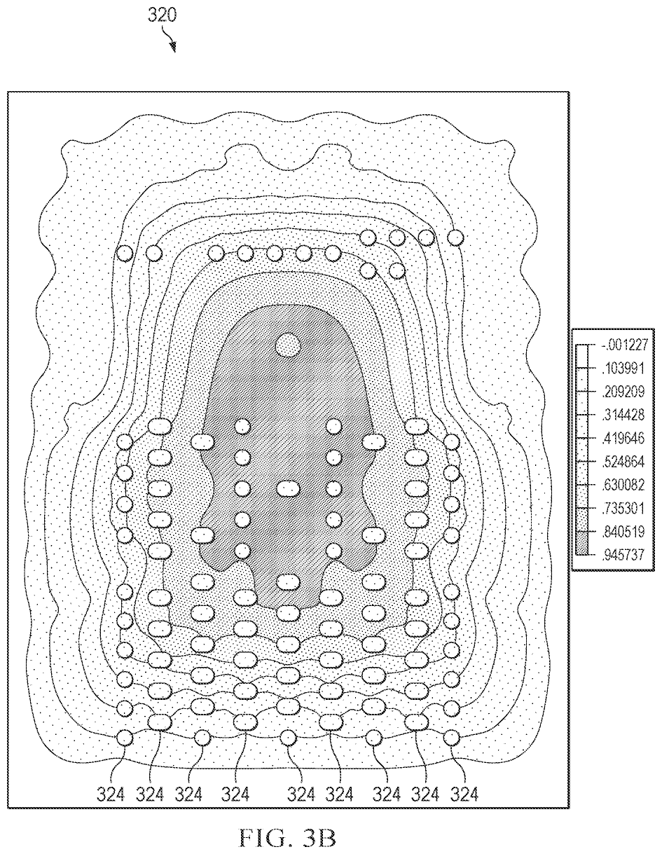

FIG. 3A illustrates a first moisture map 300 that plots moisture of a conventional IC package that does not include moisture channels. As is demonstrated by the first moisture map 300, a center region of the IC package has a greatest moisture, which can lead to delamination of layers of the IC package in some situations. FIG. 3B illustrates a second moisture map 320 that plots moisture of an IC package that includes moisture channels 324. Thus, the second moisture map 320 could represent a moisture map for the IC package 100 of FIG. 1 and/or the IC package 200 of FIG. 2. As demonstrated in the second moisture map 320, a center region of the IC package has a lower overall moisture than the IC package corresponding to the first moisture map 300. Thus, the moisture channels 324 reduce the moisture of the center region of the IC package. Moreover, as illustrated, the moisture channels 324 has a lower moisture content that a region circumscribing the moisture channels 324. That is, the moisture channels 324 have a first moisture content that is lower than a second moisture content of an area circumscribing the moisture channels 324.

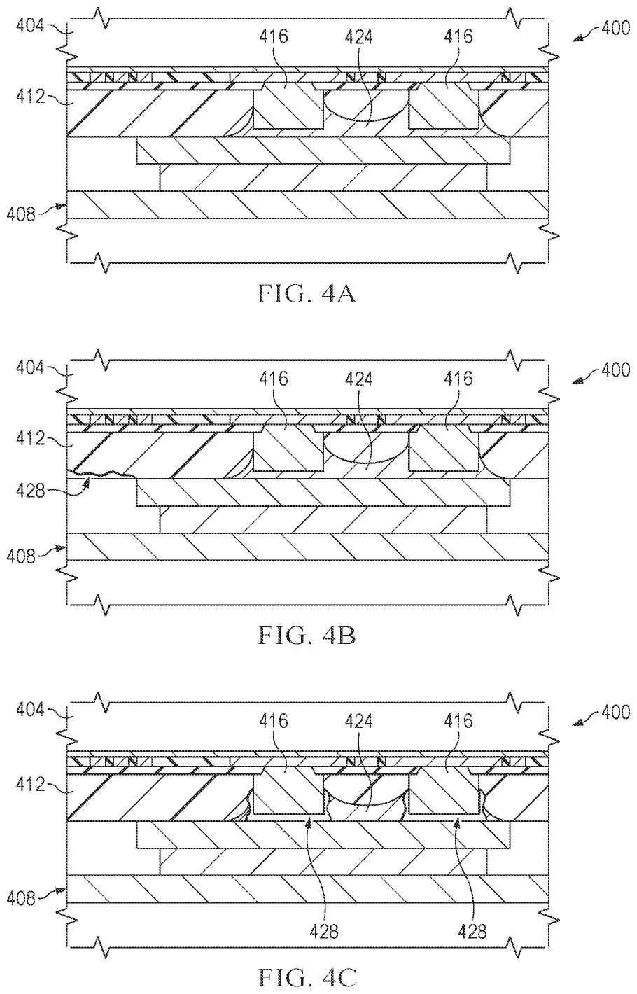

FIGS. 4A-4C illustrate delamination of an IC package, such as a conventional IC package that does not include moisture channels. Thus, FIGS. 4A-4C employ the same reference numbers to denote the same structures. FIG. 4A illustrates an IC package 400 with a die 404 mounted on an interconnect 408 (e.g. a lead frame) and encapsulated with a mold compound 412. Copper posts 416 are attached to the interconnect 408 with solder 424.

FIG. 4B illustrates the IC package 400 after a preconditioning operation. As illustrated in FIG. 4B, after the preconditioning operation, delamination 428 between the mold compound 412 and the solder 424 is formed.

FIG. 4C illustrates the IC package 400 after the preconditioning operation and after a temperature cycle. As illustrated in FIG. 4C, after the temperature cycle following the preconditioning operation, delamination 428 extends, leading to cracking of solder material and separating of the copper posts 416 and the interconnect 408, which leads to failure of the IC package 400 in some examples. However, if moisture channels were included, such as the first moisture channel 104 and the second moisture channel 108 of FIG. 1, the delamination could be curtailed in some situations.

FIGS. 5-13 illustrates stages of a method for fabricating an IC package, such as the IC package 100 of FIG. 1. Thus, FIGS. 5-13 employ the same reference numbers to denote the same structures.

In a first stage 500 of the method, as illustrated in FIG. 5, a wafer 600 is provided. The wafer 600 includes K number of dies, including a first die 604 and a Kth die 608, where K is an integer greater than or equal to one. The K number of dies include circuitry to execute a specific operation.

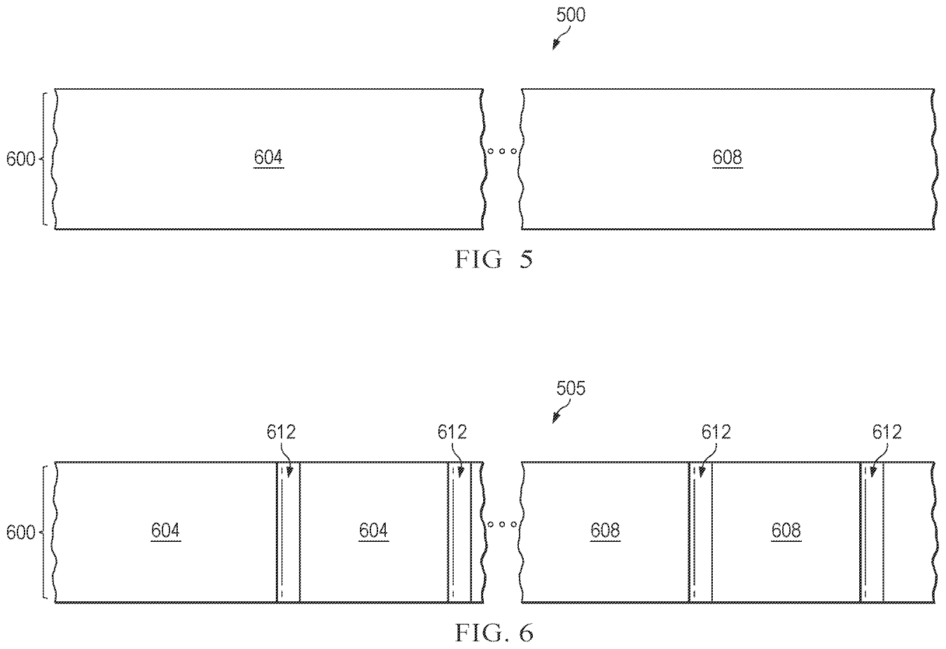

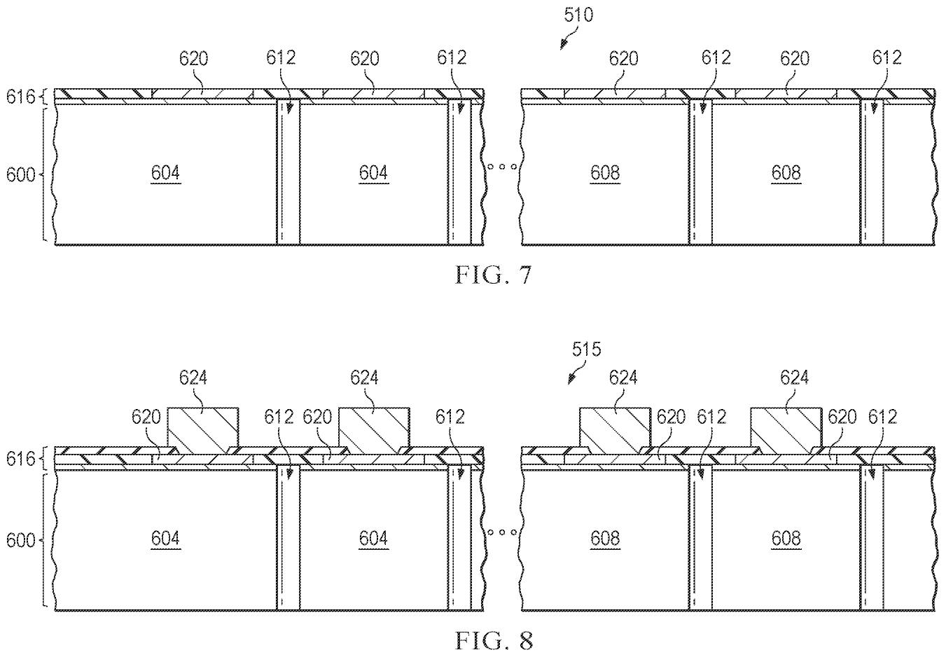

In a second stage 505 of the method, as illustrated in FIG. 6, moisture channels 612 are formed in the K number of dies, including the first die 604 and the Kth die 608. The moisture channels 612 are formed in a boring operation (e.g., a drilling operation). In some examples, the moisture channels 612 are through holes with a diameter of about 40 micrometers to about 200 micrometers (or even larger in some examples). That is, the moisture channels 612 extend between surfaces of the wafer 600.

In a third stage 510 of the method, as illustrated in FIG. 7, a metTop layer 616 is formed on the K number of dies, including the first die 604 and the Kth die 608. The metTop layer 616 refers to metal pads that are patterned to avoid an opening of the moisture channels 612. That is, the moisture channels 612 remain as through holes of the wafer 600, and metal pads of the metTop layer 616 do not interfere with the moisture channels 612. The metTop layer 616 is formed, for example, with Physical Vapor Deposition (PVD), Chemical Vapor Deposition (CVD) or electroplating and patterning and etching (e.g., with a photoresist). The metal pads of the metTop layer 616 provide bond pads 620 that are conductively coupled to internal circuits of the K number of dies, including the first die 604 and the Kth die 608.

In a fourth stage 515 of the method, as illustrated in FIG. 8, copper posts 624 are formed on the bond pads 620 of the K number of dies, including the first die 604 and the Kth die 608. The copper posts 624 are formed, for example, with an electroplating operation. The copper posts 624 enable a conductive connection to circuit components of the K number of dies.

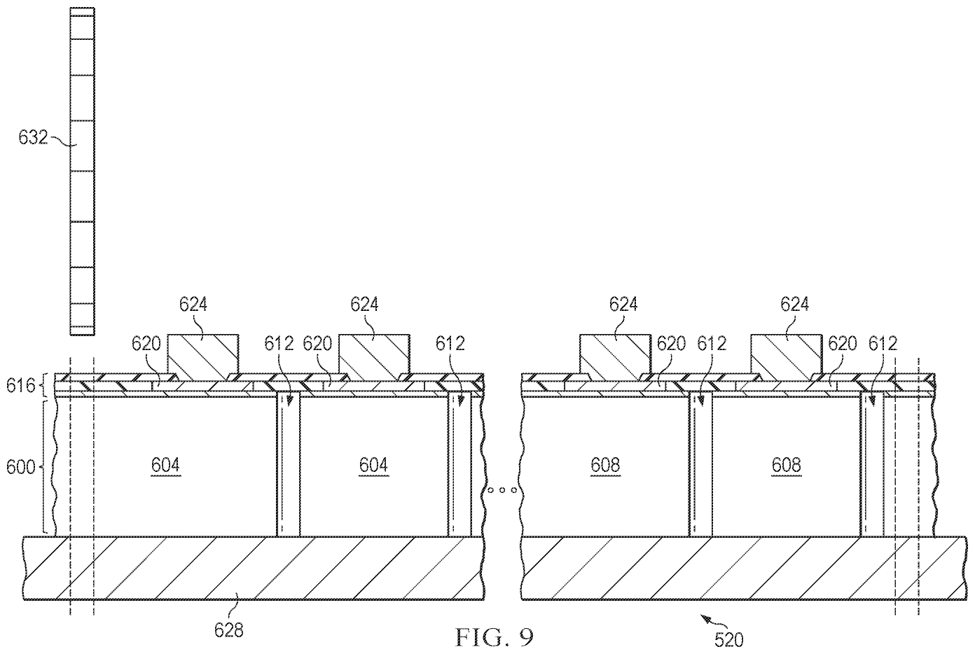

In a fifth stage 520 of the method, as illustrated in FIG. 9, the wafer 600 is placed on a dicing table 628. Additionally, in the fifth stage 520, a saw 632, such as a laser saw, a diamond saw or a plasma cutter dices the wafer 600 to singulate the K number of dies, including the first die 604 and the Kth die 608.

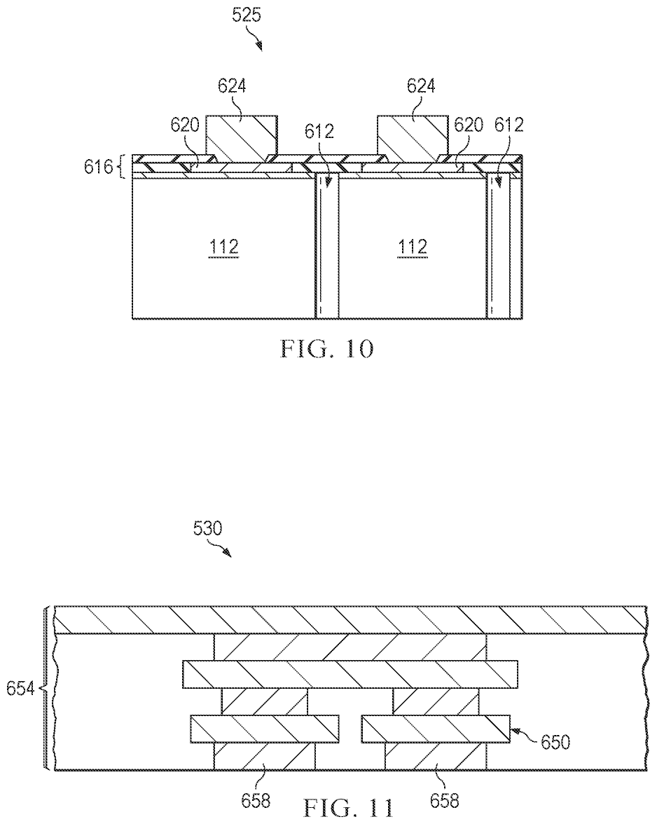

In a sixth stage 525 of the method, as illustrated in FIG. 10, the first die 604 is provided in response to the singulation. The first die 604 is employable to implement the die 112 of FIG. 1. In a seventh stage 530, as illustrated in FIG. 11, an interconnect 650 is provided. The interconnect 650 includes a substrate 654 for mounting the copper posts 624. Additionally, the interconnect 650 includes leads 658.

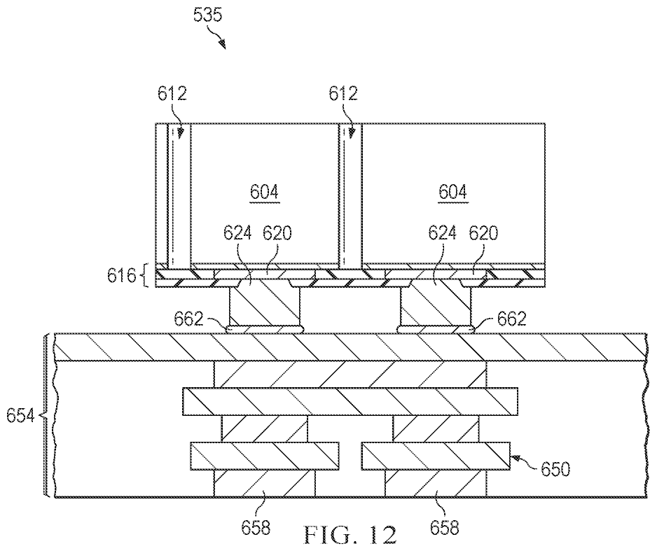

In an eighth stage 535 of the method, as illustrated in FIG. 12, the copper posts 624 are mounted on the substrate 654. More particularly, the copper posts 624 are attached to the substrate 654 (e.g., on pads of the substrate 654). The copper posts 624 are attached to the substrate 654 with solder 662 (e.g., solder paste). In some examples, the solder 662 is reflowed to adhere the bond pads 620 to the substrate 654. In this manner, the leads 658 are conductively coupled with the circuits of the first die 604 through the copper posts 624.

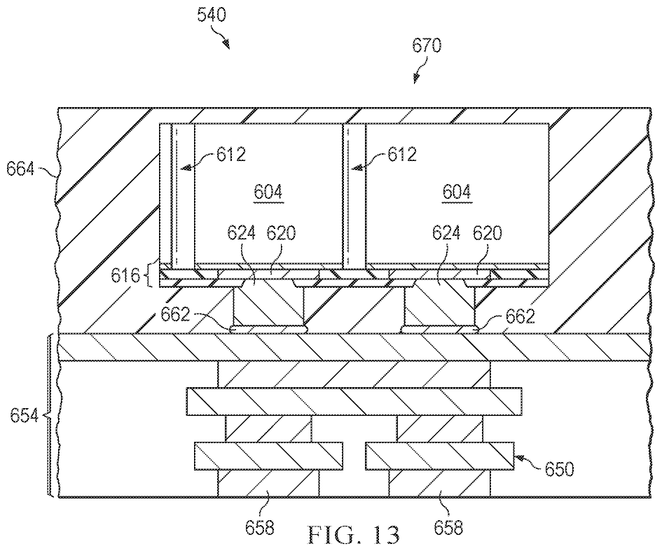

In a ninth stage 540 of the method, as illustrated in FIG. 13, a mold compound 664 is flowed over the first die 604, the copper posts 624 and the interconnect 650 in a mold flow operation. The mold compound 664 has a water vapor transmission rate of at least 3 mg/(m²d). The mold compound 664 encapsulates the first die 604, the copper posts 624 and a portion of the interconnect 650, leaving the leads 658 exposed. This forms an IC package 670, which is employable to implement the IC package 100 of FIG. 1. Thus, in some examples, the IC package 670 is a QFN IC package or a DFN IC package. During a reflow at a preconditioning operation, moisture trapped in the IC package 670 during fabrication escapes through the moisture channels 612 (through holes) and permeates through the mold compound 664 (e.g., due to the water vapor transmission rate), curtailing a chance of delamination of the layers of the IC package 670.

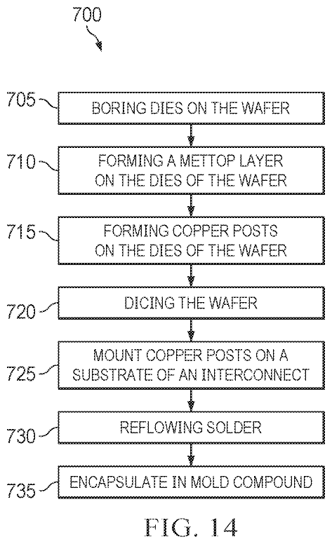

FIG. 14 illustrates a flowchart of an example method 700 for fabricating an IC package, such as the IC package 100 of FIG. 1. At block 705, moisture channels are bored in a die (e.g., the first die 604 of FIG. 6) of a wafer (e.g., the wafer 600 of FIG. 6). The moisture channels are formed with drilling in some examples. At block 710, a metTop layer (e.g., the metTop layer 616 of FIG. 7) is formed on the die of the wafer. The metTop layer provides metal pads patterned to avoid interfering with ends/openings of the moisture channels 612. The metal pads of the metTop layer provides bond pads (e.g., the bond pads 620 of FIG. 7).

At block 715, copper posts (e.g., the copper posts 624 of FIG. 8) are formed on the bond pads of the die of the wafer. The copper posts are formed, for example with electroplating of the wafer. At block 720, the wafer is diced with a saw (e.g., the saw 632) to provide the die in a singulation operation.

At block 725, the copper posts of the die are mounted on a substrate of an interconnect with solder paste. That is, in a flip chip operation, the copper posts are attached to pads on the substrate. At block 730, the solder paste is reflowed to adhere the copper posts on the substrate. At block 735, the die, the copper posts and a portion of the interconnect are encapsulated in a mold compound.

In this description, unless otherwise stated, “about” preceding a parameter means being within +/−10 percent of that parameter. Modifications are possible in the described embodiments, and other embodiments are possible, within the scope of the claims.

What is claimed is:

1. An IC (integrated circuit) package comprising:
an interconnect having a substrate with pads;
a die having moisture channels and bond pads;
copper posts formed on the bond pads of the die, wherein the copper posts are coupled of the pads of the substrate; and
a mold compound encapsulating the die, the copper posts and a portion of the interconnect.

2. The IC package of claim 1, wherein the moisture channels are through holes.

3. The IC package of claim 2, wherein the through holes have a diameter of about 40 micrometers to about 200 micrometers.

4. The IC package of claim 2, wherein the moisture channels are proximate a center of the die.

5. The IC package of claim 1, wherein the copper posts are adhered to the pads of the substrate with solder.

6. The IC package of claim 4, wherein the copper posts are formed on metal pads of a metTop layer of the die.

7. The IC package of claim 1, wherein the mold compound is plastic.

8. The IC package of claim 7, wherein the mold compound has a water vapor transmission rate of at least 3 milligrams per square meter per day.

9. The IC package of claim 1, wherein a moisture content of the moisture channels is lower than regions of the IC package circumscribing the moisture channels.

10. The IC package of claim 1, wherein the IC package is a quad flat no-leads (QFN) IC package.

11. A method for forming an IC (integrated circuit) package comprising:
boring moisture channels in a die of a wafer;
forming a metTop layer on a die of the wafer;
forming copper posts on the die of the wafer;
dicing the wafer to provide the die;
mounting the copper posts of the die on a substrate of an interconnect with solder paste;
reflowing the solder paste to adhere the copper posts on the substrate; and
encapsulating the die, the copper posts and a portion of the interconnect in a mold compound.

12. The method of claim 11, wherein the boring comprises drilling through holes in the die to provide the moisture channels.

13. The method of claim 12, wherein the through holes have a diameter of about 40 micrometers to about 200 micrometers.

14. The method of claim 11, wherein a moisture content of the moisture channels is lower than regions of the IC package circumscribing the moisture channels.

15. The method of claim 14, wherein the moisture channels in the die curtail delamination of the interconnect and the copper posts.

16. The method of claim 11, wherein the moisture channels are proximate a center of the die.

17. The method of claim 11, wherein the copper posts are mounted on pads of the substrate.

18. The method of claim 17, wherein the copper posts are formed on metal pads of a metTop layer of the die.

19. The method of claim 11, wherein the mold compound is plastic.

20. The method of claim 19, wherein the mold compound has a water vapor transmission rate of at least 3 milligrams per square meter per day.
